(19) United States
(12) Patent Application Publication
(10) Pub. No.: US 2024/0224596 A1
(43) Pub. Date: Jul. 4, 2024

(54) Display Device

(71) Applicant: LG Display Co., Ltd., Seoul (KR)

(72) Inventors: JaeHyung Jo, Goyang-si (KR); ByungSam Min, Goyang-si (KR); Wondoo Kim, Gimpo-si (KR)

(21) Appl. No.: 18/231,472

(22) Filed: Aug. 8, 2023

(30) Foreign Application Priority Data
Dec. 30, 2022 (KR) 10-2022-0191119

(51) Int. Cl. H10K 59/121; H10K 59/126

(52) U.S. Cl. CPC H10K 59/1216; H10K 59/126

(57) ABSTRACT

A display device according to an exemplary embodiment of the present disclosure includes a substrate including an emission area and a non-emission area and having a plurality of sub-pixels defined thereon, a driving transistor disposed in the non-emission area, a light emitting element disposed in the emission area, a first storage capacitor disposed in the emission area and a second storage capacitor disposed in the non-emission area.

### CROSS-REFERENCE TO RELATED APPLICATION

This application claims the benefit of and priority to Republic of Korea Patent Application No. 10-2022-0191119 filed on Dec. 30, 2022, in the Republic of Korea, the entire contents of which are incorporated herein by reference in their entirety.

### BACKGROUND

### Technical Field

The present disclosure relates to a display device, and more particularly, to a display device capable of improving luminance by securing storage capacity.

### Discussion of the Related Art

Recently, as our society advances toward an information-oriented society, the field of display devices for visually expressing an electrical information signal has rapidly advanced. Various display devices having excellent performance in terms of thinness, lightness, and low power consumption, are being developed correspondingly.

Representative display devices may include a liquid crystal display device (LCD), a field emission display device (FED), an electro-wetting display device (EWD), an organic light emitting display device (OLED), and the like.

Among these display devices, an organic light emitting display device is a self-emission display device, and can be manufactured to be light and thin since it does not require a separate light source, unlike a liquid crystal display device having a separate light source. In addition, the organic light emitting display device has advantages in terms of power consumption due to a low voltage driving, and is excellent in terms of a color implementation, a response speed, a viewing angle, and a contrast ratio (CR). Therefore, organic light emitting display devices are expected to be utilized in various fields.

### SUMMARY

Embodiments described herein include display devices capable of securing a large amount of storage capacity, reducing power consumption, and/or acquiring a high opening ratio.

Objects of the present disclosure are not limited to the above-mentioned objects, and other objects, which are not mentioned above, can be clearly understood by those skilled in the art from the following descriptions.

In one embodiment, a display device includes a substrate including an emission area and a non-emission area. The emission area includes a sub-pixel. The display device further includes a driving transistor disposed in the non-emission area, a light emitting element in the emission area, a first storage capacitor in the emission area and a second storage capacitor in the non-emission area.

In one embodiment, a display device includes a substrate having an emission area and a non-emission area, and a light emitting element on the substrate in the emission area. The light emitting element is configured to emit light. The display device also includes a driving transistor on the substrate in the non-emission area. The driving transistor is configured to drive the light emitting element. The display device also includes a first electrode and a second electrode on the substrate. The first electrode has a first portion in the emission area and a second portion in the non-emission area. The second electrode has a first portion in the emission area and a second portion in the non-emission area. The first portion of the first electrode and the first portion of the second electrode overlap each other in the emission area, such that a first storage is in the emission area. The second portion of the first electrode and the second portion of the second electrode overlap each other in the non-emission area such that a second storage capacitor is in the non-emission area.

In one embodiment, a display device includes a substrate having an emission area and a non-emission area, and a light emitting element on the substrate in the emission area. The light emitting element is configured to emit light. The display device also includes a driving transistor on the substrate in the non-emission area. The driving transistor is configured to drive the light emitting element. The display device also includes a first storage capacitor in the emission area and a second storage capacitor in the non-emission area. Both the first storage capacitor and the second storage capacitor are connected between the driving transistor and the light emitting element.

Other detailed matters of the exemplary embodiments are included in the detailed description and the drawings.

According to the present disclosure, by securing a greater amount of storage capacity, the amount of current can increase and luminance can increase when supplying an equal data voltage.

According to the present disclosure, by securing a greater amount of storage capacity, since a data voltage of a relatively low power can be applied for equal luminance, power consumption can be reduced.

According to the present disclosure, a display device capable of securing a high opening ratio while securing a greater amount of storage capacity can be provided.

The effects according to the present disclosure are not limited to the contents exemplified above, and more various effects are included in the present specification.

### BRIEF DESCRIPTION OF THE DRAWINGS

FIG. 1 is a schematic block diagram of a display device according to an exemplary embodiment of the present disclosure.

FIG. 2 is a circuit diagram of a sub-pixel of the display device according to an exemplary embodiment of the present disclosure.

FIG. 3 is a plan view illustrating a pixel of the display device according to an exemplary embodiment of the present disclosure.

FIG. 4 is a plan view illustrating a white sub-pixel of the display device according to an exemplary embodiment of the present disclosure.

FIG. 5 is a cross-sectional view taken along V-V′ of FIG. 4 according to an exemplary embodiment of the present disclosure.

FIG. 6 is a cross-sectional view taken along VI-VI′ of FIG. 4 according to an exemplary embodiment of the present disclosure.

FIG. 7 is a graph illustrating luminance according to an increase in storage capacitors of the display device according to an exemplary embodiment of the present disclosure.

FIG. 8 is a graph illustrating data voltages according to an increase in storage capacitors of the display device according to an exemplary embodiment of the present disclosure.

FIG. 9 is a cross-sectional view of an emission area of a display device according to another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure. Therefore, the present disclosure will be defined only by the scope of the appended claims.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

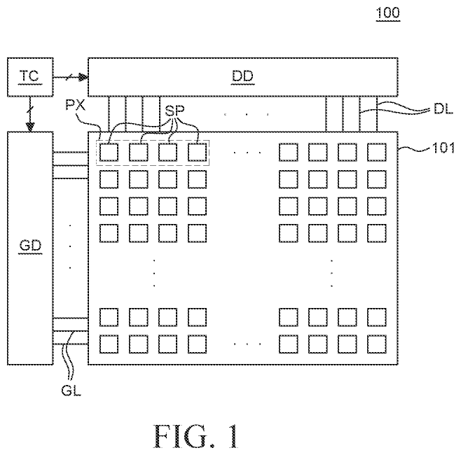

FIG. 1 is a schematic block diagram of a display device according to an exemplary embodiment of the present disclosure. Referring to FIG. 1, a display device 100 includes a display panel 101, a gate driver GD, a data driver DD, and a timing controller TC.

The display panel 101 is a panel for displaying an image. The display panel 101 may include various circuits, lines, and light emitting elements disposed on a substrate. The display panel 101 is divided by a plurality of data lines DL and a plurality of gate lines GL that cross each other, and may include a plurality of pixels PX connected to the plurality of data lines DL and the plurality of gate lines GL. The display panel 101 may include an active area defined by the plurality of pixels PX and a non-active area in which various signal lines or pads and the like are formed. The display panel 101 may be implemented as a display panel 101 used in various display devices, such as a liquid crystal display, an organic light emitting display, and an electrophoretic display. Hereinafter, the display panel 101 will be described as a panel used in an organic light emitting display, but is not limited thereto.

The timing controller TC receives timing signals such as a vertical synchronization signal, a horizontal synchronization signal, a data enable signal, and a dot clock signal through a receiving circuit such as an LVDS or TMDS interface connected to a host system. The timing controller TC generates timing control signals for controlling the data driver DD and the gate driver GD based on the timing signals input thereto.

The data driver DD supplies data voltages to a plurality of sub-pixels SP. The data driver DD may include a plurality of source drive integrated circuits (ICs). The plurality of source drive ICs may receive digital video data and a source timing control signal from the timing controller TC. The plurality of source drive ICs convert digital video data into gamma voltages in response to the source timing control signal to generate data voltages DATA, and supply the data voltages through the data lines DL of the display panel 101. The plurality of source drive ICs may be connected to the data lines DL of the display panel 101 through a COG (Chip On Glass) process or a TAB (Tape Automated Bonding) process. In addition, the source drive ICs may be formed on the display panel 101 or may be formed on a separate PCB substrate and connected to the display panel 101.

The gate driver GD supplies gate signals to the plurality of sub-pixels SP. The gate driver GD may include a level shifter and a shift register. The level shifter may shift a level of a clock signal that is input as a transistor-transistor logic (TTL) level from the timing controller TC and then, supply the shifted clock signal to the shift register. The shift register may be formed in the non-display area of the display panel 101 by a GIP (Gate In Panel) method, but is not limited thereto. The shift register may be configured to include a plurality of stages for shifting and outputting gate signals in response to the clock signal and a driving signal. The plurality of stages included in the shift register may sequentially output the gate signals through a plurality of output terminals.

The display panel 101 may include the plurality of sub-pixels SP. The plurality of sub-pixels SP may be sub-pixels SP for emitting light of different colors. For example, each of the plurality of sub-pixels SP may be a red sub-pixel, a green sub-pixel, a blue sub-pixel, and a white sub-pixel, but the present disclosure is not limited thereto. The plurality of sub-pixels SP may constitute a pixel PX. That is, the red sub-pixel, the green sub-pixel, the blue sub-pixel, and the white sub-pixel may constitute one pixel PX, and the display panel 101 may include the plurality of pixels PX.

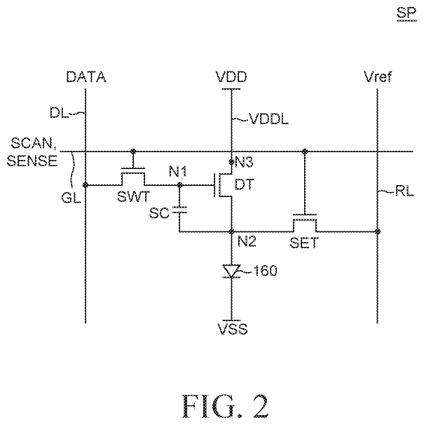

Hereinafter, a more detailed description of a driving circuit for driving one sub-pixel SP will be made with reference to FIG. 2.

FIG. 2 is a circuit diagram of a sub-pixel of the display device according to an exemplary embodiment of the present disclosure. FIG. 2 illustrates a circuit diagram of one sub-pixel SP among the plurality of sub-pixels SP of the display device 100.

Referring to FIG. 2, the sub-pixel SP may include a switching transistor SWT, a sensing transistor SET, a driving transistor DT, a storage capacitor SC, and a light emitting element 160.

The light emitting element 160 may include an anode, an organic layer, and a cathode. The organic layer may include various organic layers such as a hole injection layer, a hole transport layer, an organic light emitting layer, an electron transport layer, and an electron injection layer. The anode of the light emitting element 160 may be connected to an output terminal of the driving transistor DT, and a low potential voltage VSS may be applied to the cathode thereof. In FIG. 2, it is described that the light emitting element 160 is an organic light emitting diode, but the present disclosure is not limited thereto, and an inorganic light emitting diode, i.e., an LED, may also be used as the light emitting element 160.

Referring to FIG. 2, the switching transistor SWT is a transistor for transmitting the data voltage DATA to a first node N1 corresponding to a gate electrode of the driving transistor DT. The switching transistor SWT may include a drain electrode connected to the data line DL, a gate electrode connected to the gate line GL, and a source electrode connected to the gate electrode of the driving transistor DT. The switching transistor SWT is turned on by a scan signal SCAN applied from the gate line GL and may transmit the data voltage DATA supplied from the data line DL to the first node N1 corresponding to the gate electrode of the driving transistor DT.

Referring to FIG. 2, the driving transistor DT is a transistor for driving the light emitting element 160 by supplying driving current to the light emitting element 160. The driving transistor DT may include the gate electrode corresponding to the first node N1, a source electrode corresponding to a second node N2 and corresponding to the output terminal, and a drain electrode corresponding to a third node N3 and corresponding to an input terminal. The gate electrode of the driving transistor DT may be connected to the switching transistor SWT, the drain electrode thereof may receive a high potential power VDD through a high potential power line VDDL, and the source electrode thereof may be connected to the anode of the light emitting element 160.

Referring to FIG. 2, the storage capacitor SC is a capacitor for maintaining a voltage corresponding to the data voltage DATA during one frame. One electrode of the storage capacitor SC may be connected to the first node N1 and the other electrode of the storage capacitor SC may be connected to the second node N2. As such, the storage capacitor SC is connected between the driving transistor DT and the light emitting element 160.

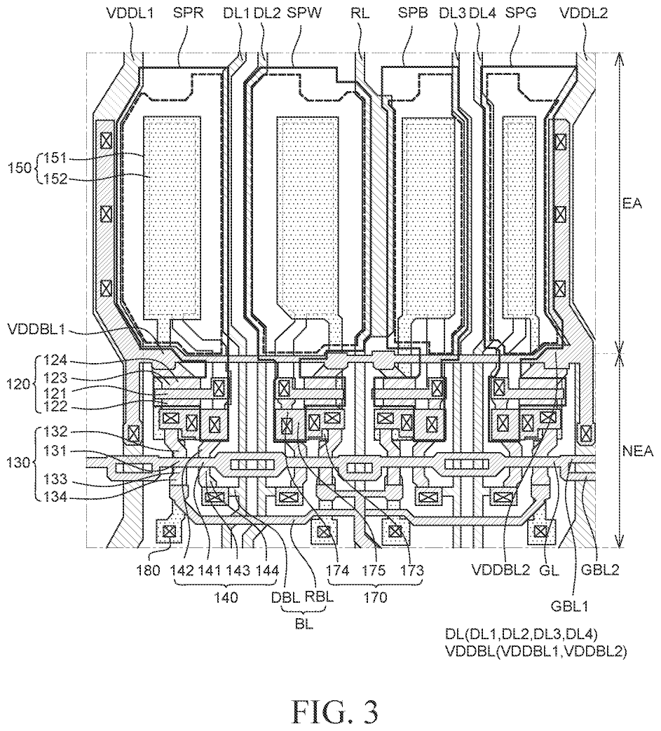

In some embodiments, the display device includes multiple storage capacitors in parallel, and each of the multiple storage capacitors is connected between the driving transistor DT and the light emitting element 160. Multiple storage capacitors enable the display device to secure a larger total storage capacitance, reduce power consumption of the display device, and/or acquire a high opening ratio. Additional details about display devices with multiple storage capacitors are further discussed below with respect to FIGS. 3-9.

Meanwhile, in the case of the display device 100, as a driving time of each sub-pixel SP increases, circuit elements such as the driving transistor DT and the like may be degraded. Accordingly, inherent characteristics of the circuit elements such as the driving transistor DT and the like may be changed. Here, the inherent characteristics of the circuit element may include a threshold voltage Vth of the driving transistor DT, a mobility a of the driving transistor DT, and the like. A change in the characteristics of the circuit element may cause a change in luminance of the corresponding sub-pixel SP. Therefore, the change in the characteristics of the circuit element may be used as the same concept as the change in luminance of the sub-pixel SP.

In addition, a degree of variation in characteristics between circuit elements of the respective sub-pixels SP may be different according to a difference in degree of degradation of the respective circuit elements. The difference in the degree of variation in characteristics between the circuit elements may cause luminance deviation between the sub-pixels SP. Therefore, characteristic deviation between the circuit elements may be used as the same concept as the luminance deviation between the sub-pixels SP. The variation in characteristics between the circuit elements, that is, luminance deviation between the sub-pixels SP, and the characteristic deviation between the circuit elements, that is, the luminance deviation between the sub-pixels SP may cause defects such as a reduction in accuracy of luminance representation of the sub-pixels SP, or occurrence of screen abnormality.

Accordingly, in the sub-pixels SP of the display device 100 according to an exemplary embodiment of the present disclosure, a sensing function for sensing characteristics of the sub-pixel SP and a compensation function for compensating the characteristics of the sub-pixel SP may be provided.

Accordingly, as shown in FIG. 2, the sub-pixel SP includes the switching transistor SWT, the driving transistor DT, the storage capacitor SC, and the light emitting element 160, and may further include the sensing transistor SET for effectively controlling a voltage state of the source electrode of the driving transistor DT.

Referring to FIG. 2, the sensing transistor SET is connected between the source electrode of the driving transistor DT and a reference line RL that supplies a reference voltage Vref, and a gate electrode thereof is connected to the gate line GL. Accordingly, the sensing transistor SET is turned on by a sensing signal SENSE applied through the gate line GL and may apply the reference voltage Vref supplied through the reference line RL to the source electrode of the driving transistor DT. Also, the sensing transistor SET may be used as one of voltage sensing paths for the source electrode of the driving transistor DT.

Referring to FIG. 2, the switching transistor SWT and the sensing transistor SET of the sub-pixel SP may share one gate line GL. That is, the switching transistor SWT and the sensing transistor SET may be applied to the same gate line GL and receive the same gate signal. For convenience of description, a voltage applied to the gate electrode of the switching transistor SWT is referred to as the scan signal SCAN, and a voltage applied to the gate electrode of the sensing transistor SET is referred to as the sensing signal SENSE, but the scan signal SCAN and the sensing signal SENSE applied to one sub-pixel SP are the same signal transmitted from the same gate line GL. Accordingly, in FIG. 3, descriptions are made by defining the scan signal SCAN and the sensing signal SENSE as gate signals.

However, the present disclosure is not limited thereto, and only the switching transistor SWT may be connected to the gate line GL, and the sensing transistor SET may be connected to a separate sensing line. Accordingly, the scan signal SCAN may be applied to the switching transistor SWT through the gate line GL, and the sensing signal SENSE may be applied to the sensing transistor SET through the sensing line.

Accordingly, the reference voltage Vref is applied to the source electrode of the driving transistor DT through the sensing transistor SET. Also, a voltage for sensing the mobility a of the driving transistor DT or the threshold voltage Vth of the driving transistor DT is detected through the reference line RL. Also, the data driver DD may compensate for the data voltage DATA according to a detected variation in the mobility a of the driving transistor DT or the threshold voltage Vth of the driving transistor DT.

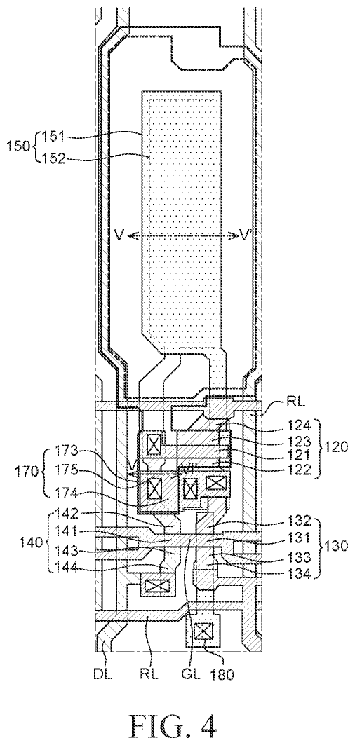

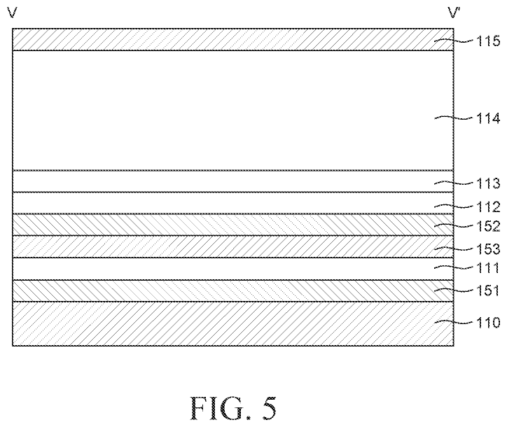

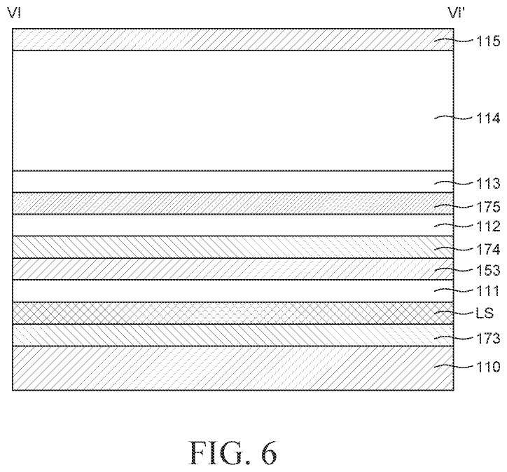

FIG. 3 is a plan view illustrating a pixel of the display device according to an exemplary embodiment of the present disclosure. FIG. 4 is a plan view illustrating a white sub-pixel of the display device according to an exemplary embodiment of the present disclosure. FIG. 5 is a cross-sectional view taken along V-V′ of FIG. 4. FIG. 6 is a cross-sectional view taken along VI-VI′ of FIG. 4.

Referring to FIGS. 3 to 6, the display device 100 according to an exemplary embodiment of the present disclosure includes a substrate 110, the gate lines GL, the data lines DL, high potential power lines VDDL, the reference line RL, the light emitting elements 160, first transistors 120, second transistors 130, third transistors 140, first storage capacitors 150, second storage capacitors 170, color filters, a buffer layer 111, a gate insulating layer 112, a passivation layer 113, a planarization layer 114, anodes 115, banks, and light emitting layers. In FIGS. 5 and 6, only components from the substrate 110 to the anode 115 among various components of the display device 100 are illustrated for convenience of description. FIGS. 5 and 6 are cross-sectional views of a white sub-pixel SPW, but a cross-sectional structure of the white sub-pixel SPW may be substantially identical to those of a red sub-pixel SPR, a blue sub-pixel SPB and a green sub-pixel SPG.

First, referring to FIG. 3, the plurality of sub-pixels SP include a red sub-pixel SPR, a white sub-pixel SPW, a blue sub-pixel SPB, and a green sub-pixel SPG, and each of the sub-pixels SP includes an emission area EA and a non-emission area NEA.

The emission area EA is an area capable of independently emitting light of one color, and the light emitting element 160 may be disposed therein. The emission area EA of the red sub-pixel SPR may be a red emission area emitting red light, the emission area EA of the white sub-pixel SPW may be a white emission area emitting white light, the emission area EA of the blue sub-pixel SPB may be a blue emission area emitting blue light, and the emission area EA of the green sub-pixel SPG may be a green emission area emitting green light.

The non-emission area NEA is an area where driving circuits for driving a plurality of the light emitting elements 160 are disposed. The first transistors 120, the second transistors 130, the third transistors 140, and the second storage capacitors 170 may be disposed in the non-emission area NEA.

Meanwhile, the non-emission areas NEA of the red sub-pixel SPR, the white sub-pixel SPW, the blue sub-pixel SPB, and the green sub-pixel SPG may have substantially similar structures. However, since the plurality of sub-pixels SP constituting one pixel PX share signal lines, the respective sub-pixels may have different structures. Referring to FIG. 3, the red sub-pixel SPR, the white sub-pixel SPW, the blue sub-pixel SPB, and the green sub-pixel SPG share the reference line RL. The red sub-pixel SPR and the white sub-pixel SPW share a first high potential power line VDDL1, and the blue sub-pixel SPB and the green sub-pixel SPG share a second high potential power line VDDL2. Accordingly, the red sub-pixel SPR and the white sub-pixel SPW may form a pair of sub-pixels, and the blue sub-pixel SPB and green sub-pixel SPG may form a pair of sub-pixels, and they may be disposed in a symmetrical structure.

Referring to FIG. 3, a plurality of the high potential power lines VDDL, the plurality of data lines DL, and the reference line RL are disposed to extend in a column direction (Y-axis direction) between the plurality of sub-pixels SP on the substrate 110. The plurality of high potential power lines VDDL, the plurality of data lines DL, and the reference line RL may be disposed on the same layer on the substrate 110 and formed of the same material. For example, the plurality of high potential power lines VDDL, the plurality of data lines DL, and the reference line RL may be formed of a conductive material such as copper (Cu), aluminum (Al), molybdenum (Mo), nickel (Ni), titanium (Ti), chromium (Cr) or an alloy thereof, but the present disclosure is not limited thereto.

The plurality of high potential power supply lines VDDL are lines that transmit power signals to each of the plurality of sub-pixels SP, and include the first high potential power line VDDL1 and the second high potential power line VDDL2. Two sub-pixels SP adjacent in a row direction (X-axis direction) may share one high potential power line VDDL among the plurality of high potential power lines VDDL. For example, the first high potential power line VDDL1 may be disposed on a left side of the red sub-pixel SPR to transmit power signals to the first transistors 120 of the red sub-pixel SPR and the white sub-pixel SPW. The second high potential power line VDDL2 may be disposed on a right side of the green sub-pixel SPG to transmit power signals to the first transistors 120 of the blue sub-pixel SPB and the green sub-pixel SPG.

The plurality of data lines DL are lines that transmit data signals to each of the plurality of sub-pixels SP, and include a first data line DL1, a second data line DL2, a third data line DL3, and a fourth data line DL4. The first data line DL1 is disposed between the red sub-pixel SPR and the white sub-pixel SPW, that is, on a right side of the red sub-pixel SPR, and may transmit data signals to the third transistor 140 of the red sub-pixel SPR. The second data line DL2 is disposed between the first data line DL1 and the white sub-pixel SPW, that is, on a left side of the white sub-pixel SPW, and may transmit data signals to the third transistor 140 of the white sub-pixel SPW. The third data line DL3 is disposed between the blue sub-pixel SPB and the green sub-pixel SPG, that is, on a right side of the blue sub-pixel SPB, and may transmit data signals to the third transistor 140 of the blue sub-pixel SPB. The fourth data line DL4 is disposed between the third data line DL3 and the green sub-pixel SPG, that is, on a left side of the green sub-pixel SPG, and may transmit data signals to the third transistor 140 of the green sub-pixel SPG.

The reference line RL is a line that transmits a reference signal to each of the plurality of sub-pixels SP, and may be disposed between the white sub-pixel SPW and the blue sub-pixel SPB. The plurality of sub-pixels SP constituting one pixel may share one reference line RL. The reference line RL may transmit a reference signal to the second transistors 130 of the red sub-pixel SPR, the white sub-pixel SPW, the blue sub-pixel SPB, and the green sub-pixel SPG.

The gate line GL disposed in the non-emission area NEA transmits a gate signal to each of the plurality of sub-pixels SP and extends in the row direction while crossing the plurality of sub-pixels SP. Since scan signals are sequentially supplied to the gate line GL under a control of the timing controller, the gate line GL may also be referred to as a scan line. As shown in FIG. 3, in the present disclosure, a single scan line structure in which the second transistor 130 and the third transistor 140 operate with one gate line GL is described mainly, but a two-scan line structure including two gate lines GL may also be applied in the same manner.

In particular, the gate line GL may use a gate redundancy structure in an area where the gate line GL and a plurality of signal lines cross each other. The gate redundancy structure is formed by branching the gate line GL into two lines only in an area where the gate line GL and the plurality of signal lines cross each other. The gate redundancy structure may include a second bridge line GBL2 extending along the gate line GL and branching downward in the Y-axis direction, and a first bridge line GBL1 extending along the gate line GL and branching upward in the Y-axis direction.

However, since each of the signal lines needs to transmit a signal to the plurality of sub-pixels SP, branch lines BL extending from each of the signal lines are required. The branch lines BL may include a first high potential power branch line VDDBL1 extending from the first high potential power line VDDL1, a second high potential power branch line VDDBL2 extending from the second high potential power line VDDL2, a data branch line DBL extending from the data line DL, and a reference branch line RBL extending from the reference line RL. The first high potential power branch line VDDBL1 and the second high potential power branch line VDDBL2 may be connected to the first high potential power line VDDL1 and the second high potential power line VDDL2, respectively, and apply a high potential power to the plurality of sub-pixels SP. The data branch line DBL may be connected to the plurality of data lines DL to apply data voltages to the plurality of sub-pixels SP, and the reference branch line RBL may be connected to the reference line RL to apply the reference voltage Vref to the plurality of sub-pixels SP.

The branch lines BL may be integrally formed and extended from the signal lines electrically connected to each other. In this case, since the branch lines BL are formed of the same material on the same layer as the signal lines, the branch lines BL may be formed of a conductive material such as copper (Cu), aluminum (Al), molybdenum (Mo), nickel (Ni), titanium (Ti), chromium (Cr) or an alloy thereof, but the present disclosure is not limited thereto.

However, the branch lines BL may be formed on a layer different from those of the signal lines and electrically connected thereto through a contact hole.

The buffer layer 111 may be disposed on the plurality of high potential power lines VDDL, the plurality of data lines DL, and the reference line RL. The buffer layer 111 may reduce penetration of moisture or impurities through the substrate 110. The buffer layer 111 may be configured to include, for example, a single layer or multilayers of silicon oxide (SiOx) or silicon nitride (SiNx), but is not limited thereto. However, the buffer layer 111 may be omitted depending on a type of the substrate 110 or a type of a thin film transistor, but is not limited thereto. In some embodiments, the buffer layer 111 extends across the emission area EA and non-emission area NEA.

Referring to FIGS. 3 to 6, a light blocking layer LS is disposed between the substrate 110 and the buffer layer 111 in the non-emission area NEA. The light blocking layer LS is disposed to overlap a first active layer 124 of at least the first transistor 120 among a plurality of the transistors 120, 130, and 140 and blocks light incident on the first active layer 124. If the first active layer 124 is irradiated with light, leakage current is generated, and thus reliability of the first transistor 120 serving as a driving transistor may be degraded. In this case, if the light blocking layer LS formed of an opaque conductive material such as copper (Cu), aluminum (Al), molybdenum (Mo), nickel (Ni), titanium (Ti), chromium (Cr) or an alloy thereof is disposed to overlap the first active layer 124, light incident from a lower portion of the substrate 110 to the first active layer 124 may be blocked, thereby improving reliability of the first transistor 120. However, the present disclosure is not limited thereto, and the light blocking layer LS may also be disposed to overlap a second active layer 134 of the second transistor 130 and a third active layer 144 of the third transistor 140.

Referring to FIG. 3, the first transistor 120 is disposed in the non-emission area NEA of each of the red sub-pixel SPR, the white sub-pixel SPW, the blue sub-pixel SPB, and the green sub-pixel SPG. The first transistor 120 includes a first gate electrode 121, a first source electrode 122, a first drain electrode 123, and the first active layer 124. The first transistor 120 electrically connected to the anode 115 of the light emitting element 160 and the high potential power line VDDL may be the driving transistor DT.

The first active layer 124 may be formed of a semiconductor material such as an oxide semiconductor, amorphous silicon, or polysilicon, but is not limited thereto. For example, when the first active layer 124 is formed of an oxide semiconductor, the first active layer 124 includes a channel region, a source region, and a drain region, and the source region and the drain region are conductive. In some embodiments, the source region includes the first source electrode 122, and the drain region may include the first drain electrode 123. However, the present disclosure is not limited thereto. Alternatively, an auxiliary metal layer or a transparent oxide layer may be further disposed on a partial area of the first active layer 124 for conductorization. In this case, the auxiliary metal layer may be formed of an opaque metal layer such as moly-titanium (MoTi), and the transparent oxide layer may be formed of a transparent conductive material such as tin oxide (TO), indium tin oxide (ITO), indium zinc oxide (IZO), indium tin zinc oxide (ITZO) or the like, but is not limited thereto.

The gate insulating layer 112 may be disposed on the first active layer 124. The gate insulating layer 112 may be a layer for insulating the first gate electrode 121 and the first active layer 124. For example, the gate insulating layer 112 may be formed of a single layer or multiple layers of silicon oxide (SiOx) or silicon nitride (SiNx), but is not limited thereto.

The first gate electrode 121 may be disposed on the gate insulating layer 112 to overlap the first active layer 124 in each of the red sub-pixel SPR, the white sub-pixel SPW, the blue sub-pixel SPB, and the green sub-pixel SPG. The first gate electrode 121 may be formed of a conductive material such as copper (Cu), aluminum (Al), molybdenum (Mo), nickel (Ni), titanium (Ti), chromium (Cr), or an alloy thereof, but is not limited thereto.

The second transistor 130 is disposed in the non-emission area NEA of each of the red sub-pixel SPR, the white sub-pixel SPW, the blue sub-pixel SPB, and the green sub-pixel SPG. The second transistor 130 includes a second gate electrode 131, a second source electrode 132, a second drain electrode 133, and the second active layer 134. The second transistor 130 electrically connected to the reference line RL and the gate line GL, and the second storage capacitor 170 may be the sensing transistor SET.

The second active layer 134 may be formed of a semiconductor material such as an oxide semiconductor, amorphous silicon, or polysilicon, but it is not limited thereto. For example, when the second active layer 134 is formed of an oxide semiconductor, the second active layer 134 includes a channel region, a source region, and a drain region, and the source region and the drain region are conductive. In some embodiments, the source region may include the second source electrode 132, and the drain region may include the second drain electrode 133. However, the present disclosure is not limited thereto. Alternatively, an auxiliary metal layer or a transparent oxide layer may be further disposed on a partial area of the second active layer 134 for conductorization. In some embodiments, the auxiliary metal layer may be formed of an opaque metal layer such as moly-titanium (MoTi), and the transparent oxide layer may be formed of a transparent conductive material such as tin oxide (TO), indium tin oxide (ITO), indium zinc oxide (IZO), indium tin zinc oxide (ITZO) or the like, but is not limited thereto.

The gate insulating layer 112 may be disposed on the second active layer 134. The gate insulating layer 112 may be a layer for insulating the second gate electrode 131 and the second active layer 134. For example, the gate insulating layer 112 may be formed of a single layer or multiple layers of silicon oxide (SiOx) or silicon nitride (SiNx), but is not limited thereto.

The second gate electrode 131 may be disposed on the gate insulating layer 112 to overlap the second active layer 134 in each of the red sub-pixel SPR, the white sub-pixel SPW, the blue sub-pixel SPB, and the green sub-pixel SPG. The second gate electrode 131 may be formed of a conductive material such as copper (Cu), aluminum (Al), molybdenum (Mo), nickel (Ni), titanium (Ti), chromium (Cr), or an alloy thereof, but is not limited thereto. The second gate electrode 131 may be a part of the gate line GL. That is, a part of the gate line GL may function as the second gate electrode 131.

The reference line RL is electrically connected to the second drain electrode 133. Specifically, the second drain electrode 133 may be electrically connected to the reference branch line RBL, which is electrically connected to the reference line RL.

The gate line GL is a line that transmits a gate signal to each of the plurality of sub-pixels SP, and extends in the row direction while crossing the plurality of sub-pixels SP. For example, the gate line GL may extend in the row direction between the non-emission area NEA and the emission area EA of each of the plurality of sub-pixels SP, and across the plurality of high potential power lines VDDL, the plurality of data lines DL, and the reference line RL that extend in the column direction.

The third transistor 140 is disposed in the non-emission area NEA of each of the red sub-pixel SPR, the white sub-pixel SPW, the blue sub-pixel SPB, and the green sub-pixel SPG. The third transistor 140 includes a third gate electrode 141, a third source electrode 142, a third drain electrode 143, and the third active layer 144. The third transistor 140 electrically connected to the gate line GL, the data line DL, and the first gate electrode 121 of the first transistor 120 may be the switching transistor SWT.

The third active layer 144 may be formed of a semiconductor material such as an oxide semiconductor, amorphous silicon, or polysilicon, but is not limited thereto. For example, when the third active layer 144 is formed of an oxide semiconductor, the third active layer 144 includes a channel region, a source region, and a drain region, and the source region and the drain region are conductive. In some embodiments, the source region may include the third source electrode 142, and the drain region may include the third drain electrode 143. However, the present disclosure is not limited thereto. Alternatively, an auxiliary metal layer or a transparent oxide layer may be further disposed on a partial area of the third active layer 144 for conductorization. In this case, the auxiliary metal layer may be formed of an opaque metal layer such as moly-titanium (MoTi), and the transparent oxide layer may be formed of a transparent conductive material such as tin oxide (TO), indium tin oxide (ITO), indium zinc oxide (IZO), indium tin zinc oxide (ITZO) or the like, but is not limited thereto.

The gate insulating layer 112 may be disposed on the third active layer 144. The gate insulating layer 112 may be a layer for insulating the third gate electrode 141 and the third active layer 144. For example, the gate insulating layer 112 may be formed of a single layer or multiple layers of silicon oxide (SiOx) or silicon nitride (SiNx), but is not limited thereto.

The third gate electrode 141 may be disposed on the gate insulating layer 112 to overlap the third active layer 144 in each of the red sub-pixel SPR, the white sub-pixel SPW, the blue sub-pixel SPB, and the green sub-pixel SPG. The third gate electrode 141 may be formed of a conductive material such as copper (Cu), aluminum (Al), molybdenum (Mo), nickel (Ni), titanium (Ti), chromium (Cr), or an alloy thereof, but is not limited thereto. The third gate electrode 141 may be the gate line GL. That is, a part of the gate line GL may function as the third gate electrode 141.

Next, the passivation layer 113 may be disposed on the first transistor 120, the second transistor 130, the third transistor 140, the plurality of high potential power lines VDDL, the plurality of data lines DL, the reference line RL, and the gate line GL. The passivation layer 113 is an insulating layer for protecting components under the passivation layer 113. For example, the passivation layer 113 may be formed of a single layer or multiple layers of silicon oxide (SiOx) or silicon nitride (SiNx), but is not limited thereto. Also, the passivation layer 113 may be omitted according to embodiments.

A plurality of color filters are disposed on the passivation layer 113. Specifically, a plurality of color filters may be disposed between the planarization layer 114 and the passivation layer 113. The plurality of color filters include a red color filter, a green color filter, and a blue color filter. The red color filter is disposed on the emission area EA of the red sub-pixel SPR, the blue color filter is disposed on the emission area EA of the blue sub-pixel SPB, and the green color filter is disposed on the emission area EA of the green sub-pixel SPG. However, a plurality of color filters are not disposed on the emission area EA of the white color filter SPW.

The planarization layer 114 may be disposed on the passivation layer 113 and the color filters. The planarization layer 114 is an insulating layer that planarizes an upper portion of the substrate 110 on which the first transistor 120, the second transistor 130, the third transistor 140, the plurality of high potential power lines VDDL, the plurality of data lines DL, the reference line RL and the gate line GL are disposed. The planarization layer 114 may be formed of an organic material, and may include, for example, a single layer or multilayers of polyimide or photoacrylic, but is not limited thereto.

The light emitting element 160 is disposed in each of the plurality of sub-pixels SP. The light emitting element 160 is disposed on the planarization layer 114 in each of the plurality of sub-pixels SP. The light emitting element 160 includes the anode 115, a light emitting layer, and a cathode.

The anode 115 is disposed on the planarization layer 114 in the emission area EA. Since the anode 115 supplies holes to the light emitting layer, it may be formed of a conductive material having a high work function. The anode 115 may be formed of a transparent conductive material, for example, indium tin oxide (ITO) or indium zinc oxide (IZO), but is not limited thereto.

Meanwhile, when the display device 100 according to an exemplary embodiment of the present disclosure is a top emission type, a reflective layer formed of a metal material having excellent reflective efficiency, such as aluminum (Al) or silver (Ag), may be added below the anode 115 so that light emitted from the light emitting layer is reflected by the anode 115 and directed upward, that is, toward the cathode. Conversely, when the display device 100 is a bottom emission type, the anode 115 may be formed of only a transparent conductive material. In addition, the anode 115 is provided over an entirety of the emission area EA and is integrally provided and extends to the non-emitting area NEA. The anode 115 disposed in the non-emission area NEA may be connected to the first source electrode 122 of the first transistor 120 and configured to receive an electrical signal.

The light emitting layer is disposed on the anode 115 in the emission area EA and the non-emission area NEA. The light emitting layer may be formed as a single layer over the plurality of sub-pixels SP. That is, respective light emitting layers of the plurality of sub-pixels SP may be connected to each other and integrally formed. The light emitting layer may be formed of one light emitting layer or may have a structure in which a plurality of light emitting layers emitting light of different colors are stacked. The light emitting layer may further include organic layers such as a hole injection layer, a hole transport layer, an electron transport layer, and an electron injection layer.

The cathode is disposed on the light emitting layer in the emission area EA and the non-emission area NEA. Since the cathode supplies electrons to the light emitting layer, it may be formed of a conductive material having a low work function. The cathode may be formed as one layer over the plurality of sub-pixels SP. That is, the cathodes of the plurality of respective sub-pixels SP may be connected to each other and integrally formed. The cathode may be formed of, for example, a transparent conductive material such as indium tin oxide (ITO) or indium zinc oxide (IZO) or a ytterbium (Yb) alloy, and may further include a metal-doped layer, but the present disclosure is not limited thereto. Meanwhile, although not shown in FIGS. 3 to 6, the cathode of the light emitting element 160 may be electrically connected to a low potential power line and receive a low potential power signal.

The first storage capacitor 150 is disposed in the emission area EA of each of the red sub-pixel SPR, the white sub-pixel SPW, the blue sub-pixel SPB, and the green sub-pixel SPG. The first storage capacitor 150 includes a first capacitor electrode 151 and a second capacitor electrode 152.

Referring to FIGS. 4 and 5, the first capacitor electrode 151 may be disposed between the substrate 110 and the buffer layer 111, where the buffer layer 111 is stacked on the substrate 110. In addition, the first capacitor electrode 151 may be disposed in the non-emission area NEA and disposed on the same layer as the light blocking layer LS placed between the substrate 110 and the first active layer 124 of the first transistor 120. For example, the first capacitor electrode 151 may be disposed on the substrate 110 directly in contact with the substrate 110 and may extend to the non-emission area NEA. In this case, the first capacitor electrode 151 may be formed of a transparent conductive material. For example, the first capacitor electrode 151 may be formed of a transparent conductive material such as indium tin oxide (ITO) or indium zinc oxide (IZO).

The second capacitor electrode 152 is disposed on the buffer layer 111 and is disposed to overlap the first capacitor electrode 151. Also, the second capacitor electrode 152 may be disposed on the same layer as the first active layer 124 of the first transistor 120. For example, the second capacitor electrode 152 may be disposed to overlap the first capacitor electrode 151 in the emission area EA. The second capacitor electrode 152 may be formed of a transparent conductive material. In some embodiments, the second capacitor electrode 152 may be formed of a transparent oxide layer disposed on the semiconductor layer 153. For example, the semiconductor layer 153 may be formed of an oxide semiconductor material such as indium gallium zinc oxide (IGZO), zinc tin oxide (ZTO), or zinc indium oxide (ZIO). The transparent oxide layer may be formed of a transparent conductive material such as tin oxide (TO), indium tin oxide (ITO), indium zinc oxide (IZO), indium tin zinc oxide (ITZO), or the like, but the present disclosure is not limited thereto. In some embodiments, the semiconductor layer 153 extends across the emission area EA and non-emission area NEA.

An area of the first capacitor electrode 151 may be greater than that of the second capacitor electrode 152. When the first capacitor electrode 151 and the second capacitor electrode 152 are sequentially deposited, an arrangement of the first capacitor electrode 151 and the second capacitor electrode 152 may be out of alignment, thereby causing a change in capacitance. However, in the display device 100 according to an exemplary embodiment of the present disclosure, by forming the area of the first capacitor electrode 151 to be greater than that of the second capacitor electrode 152, a change in capacitance may not be caused even if the arrangement of the first capacitor electrode 151 and the second capacitor electrode 152 is out of alignment.

The anode 115 of the light emitting element 160 is disposed on the second capacitor electrode 152 in the emission area EA to overlap the second capacitor electrode 152. Accordingly, the first storage capacitor 150 may be formed by overlapping the first capacitor electrode 151, the second capacitor electrode 152, and the anode 115.

The second storage capacitor 170 is disposed in the non-emission area EA of each of the red sub-pixel SPR, the white sub-pixel SPW, the blue sub-pixel SPB, and the green sub-pixel SPG. The second storage capacitor 170 includes a third capacitor electrode 173 and a fourth capacitor electrode 174.

Referring to FIGS. 4 and 6, the third capacitor electrode 173 extends from the first capacitor electrode 151 and is disposed on the same layer as the first capacitor electrode 151. The third capacitor electrode 173 may be formed integrally with the first capacitor electrode 151 and may be a portion that extends from the first capacitor electrode 151 and is disposed in the non-emission area EA. For example, the third capacitor electrode 173 may be a portion extending from the first capacitor electrode 151 and directly in contact with a lower portion of the light blocking layer LS disposed in the non-emission area EA. In this case, the third capacitor electrode 173 may be formed of a transparent conductive material such as tin oxide (TO), indium tin oxide (ITO), indium zinc oxide (IZO), indium tin zinc oxide (ITZO) or the like, in the same manner as the first capacitor electrode 151. The light blocking layer LS may be formed of a metal layer such as copper (Cu), aluminum (Al), molybdenum (Mo), nickel (Ni), titanium (Ti), chromium (Cr), or the like. Also, the third capacitor electrode 173 may be integrally formed with the light blocking layer LS. In this case, a portion of the third capacitor electrode 173 connected to the first capacitor electrode 151 may be formed of the same transparent conductive material as the first capacitor electrode 151, and a remaining portion of the third capacitor electrode 173 may be formed of a metal layer.

The third capacitor electrode 173 may be connected to the third source electrode 143 of the third transistor 140 through a contact hole. That is, the first capacitor electrode 151 and the third capacitor electrode 173 may be electrically connected to the third source electrode 143 of the third transistor 140.

The fourth capacitor electrode 174 extends from the second capacitor electrode 152 and is disposed on the same layer as the second capacitor electrode 152. The fourth capacitor electrode 174 may be formed integrally with the second capacitor electrode 152 and may be a portion that extends from the second capacitor electrode 152 and is disposed in the non-emission area EA. In this case, the fourth capacitor electrode 174 may be formed of a transparent oxide layer disposed on the semiconductor layer 153 in the same manner as the second capacitor electrode 152. In this case, the semiconductor layer 153 may be formed of an oxide semiconductor material such as indium gallium zinc oxide (IGZO), zinc tin oxide (ZTO), or zinc indium oxide (ZIO). The transparent oxide layer may be formed of a transparent conductive material such as tin oxide (TO), indium tin oxide (ITO), indium zinc oxide (IZO), indium tin zinc oxide (ITZO) or the like, but the present disclosure is not limited thereto.

The fourth capacitor electrode 174 integrally extends with the second source electrode 132 of the second transistor 130 and may be electrically connected to the first gate electrode 121 of the first transistor 120 through a contact hole. That is, the second capacitor electrode 152 and the fourth capacitor electrode 174 may be electrically connected to the first gate electrode 121 of the first transistor 120.

A fifth capacitor electrode 175 may be disposed on the fourth capacitor electrode 174 in the non-emission area EA to overlap the fourth capacitor electrode 174. The fifth capacitor electrode 175 may be disposed on the same layer as the first gate electrode 121 of the first transistor 120. In this case, the fifth capacitor electrode 175 may be formed of a conductive material, such as copper (Cu), aluminum (Al), molybdenum (Mo), nickel (Ni), titanium (Ti), chromium (Cr) or an alloy thereof, in the same manner as the first gate electrode 121, but the present disclosure is not limited thereto.

The fifth capacitor electrode 175 may be connected to the third source electrode 143 of the third transistor 140 through a contact hole. That is, the fifth capacitor electrode 175 may be electrically connected to the third source electrode 143 of the third transistor 140.

Accordingly, the second storage capacitor 170 may be formed by overlapping the third capacitor electrode 173, the fourth capacitor electrode 174, and the fifth capacitor electrode 175.

Meanwhile, referring to FIGS. 3 and 4, repair units 180 extending from the third capacitor electrodes 173 of the respective sub-pixels SPR, SPW, SPB, and SPG to adjacent sub-pixels SPR, SPW, SPB, and SPG of the same colors may be disposed. The repair units 180 may be disposed to partially overlap the emission areas EA of the adjacent sub-pixels SPR, SPW, SPB, and SPG of the same colors. The repair unit 180 may be formed of the same material as the third capacitor electrode 173 and disposed on the same layer. For example, the repair units 180 may be formed of a transparent conductive material such as tin oxide (TO), indium tin oxide (ITO), indium zinc oxide (IZO), indium tin zinc oxide (ITZO) or the like, but the present disclosure is not limited thereto. The repair units 180 may be disposed to overlap the anodes 115 of the adjacent sub-pixels SPR, SPW, SPB, and SPG of the same colors with the buffer layer 111 interposed therebetween.

In the display device 100 as described above, when a defective pixel occurs, a repair process is required for the corresponding pixel. In the repair process, a line for the defective pixel is connected to an adjacent pixel of the same color using a laser, so that the defective pixel may be normally operated. Accordingly, in the display device 100 according to an exemplary embodiment of the present disclosure, when a defect occurs in the sub-pixels SPR, SPW, SPB, and SPG, the anodes 115 of adjacent sub-pixels SPR, SPW, SPB, and SPG of the same colors and the repair units 180 are connected through the repair process, so that the defective sub-pixels SPR, SPW, SPB, and SPG may also be operated normally.

However, since a conventional repair unit is disposed in the non-emission area NEA, which is an area where the driving circuit is disposed, the non-emission area NEA is inevitably widened, and thus, there is a defect in which an opening ratio is reduced. Unlike this, in the display device 100 according to an exemplary embodiment of the present disclosure, the repair unit 180 formed of a transparent conductive material, which is extending from the third capacitor electrode 173, may be disposed in the emission area EA of the adjacent sub-pixel SPR, SPW, SPB, or SPG from the third capacitor electrode 173. Accordingly, a repair process for a defective pixel may be facilitated, and an opening ratio may be increased by reducing an area of the non-emission area NEA.

Notably, as illustrated in FIGS. 3-6, in some embodiments, the first electrode 151 and the third electrode 173 are on a same layer and electrically connected to each other; and the second electrode 152 and the fourth electrode 174 are on a same layer and electrically connected to each other. As such, the first electrode 151 and the third electrode 173 may be deemed as a single lower electrode having a first portion in the emission area EA (corresponding to the first electrode 151) and a second portion in the non-emission area NEA (corresponding to the third electrode 173). Similarly, the second electrode 152 and the fourth electrode 174 may be deemed as a single upper electrode having a first portion in the emission area EA (corresponding to the second electrode 152) and a second portion in the non-emission area NEA (corresponding to the fourth electrode 174). The first portion of the lower electrode and the first portion of the upper electrode overlap each other in the emission area EA such that a first storage capacitor 150 is in the emission area EA, and the second portion of the lower electrode and the second portion of the upper electrode overlap each other in the non-emission area NEA such that a second storage capacitor 170 is in the non-emission area NEA.

Further, similar to the storage capacitor SC shown in FIG. 2, each of the first storage capacitor 150 and the second storage capacitor 170 is connected between a driving transistor (e.g., the first transistor 120) and a light emitting element (not shown in FIGS. 3-6).

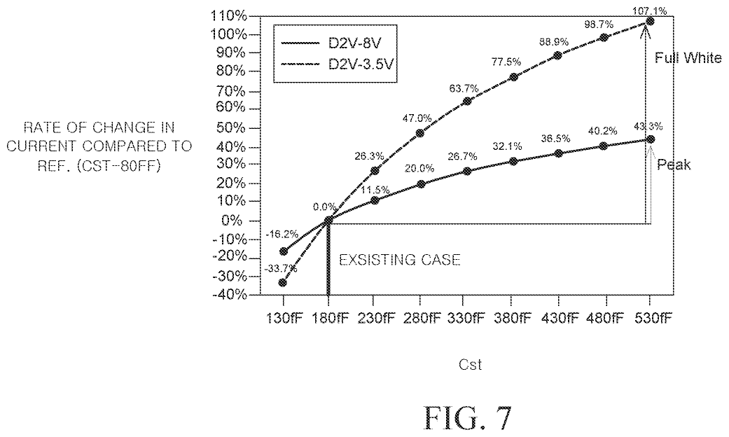

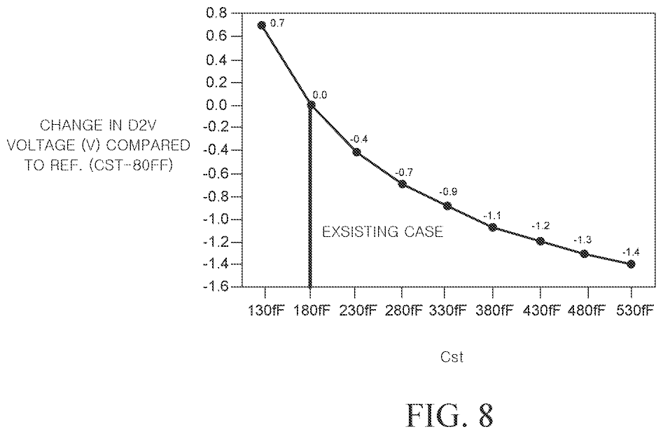

FIG. 7 is a graph illustrating luminance according to an increase in storage capacitors of the display device according to an exemplary embodiment of the present disclosure. FIG. 8 is a graph illustrating data voltages according to an increase in storage capacitors of the display device according to an exemplary embodiment of the present disclosure.

Effects of the display device 100 according to an exemplary embodiment of the present disclosure will be described with reference to FIGS. 7 and 8.

Referring to FIG. 7, the display device 100 according to an exemplary embodiment of the present disclosure can secure a storage capacitor of 500 fF or more by disposing a storage capacitor not only in the non-emission area NEA but also in the emission area EA. In addition, when supplying an equal data voltage, the amount of current increases compared to an existing storage capacity of 180 fF, resulting in an improvement of 107% for white color and an improvement of 43% for peak luminance. Accordingly, when a greater amount of storage capacity is secured and an equal data voltage is supplied, the amount of current increases and thus, the luminance can be increased.

In addition, referring to FIG. 8, the display device 100 according to an exemplary embodiment of the present disclosure has a reduction in data voltage by 1.4V compared to the existing storage capacity of 180 fF when luminance is equal, by disposing a storage capacitor not only in the non-emission area NEA but also in the emission area EA. Accordingly, since a greater amount of storage capacity can be secured and a relatively low data voltage can be applied for the same luminance, power consumption can be reduced.

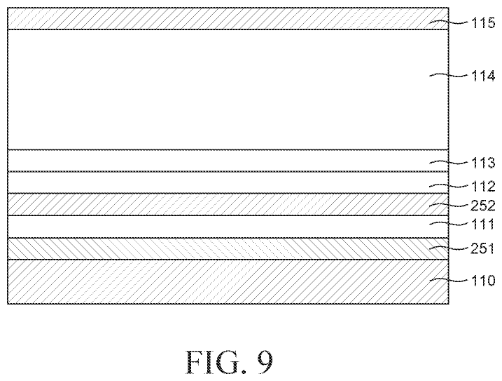

FIG. 9 is a cross-sectional view of an emission area of a display device according to another exemplary embodiment of the present disclosure.

Since other configurations of a display device 200 of FIG. 9 are substantially identical to those of the display device 100 of FIGS. 1 to 6, except for the first storage capacitor 250 in FIGS. 1-6 is in the emission area EA, while the first storage capacitor 250 in FIG. 9 is in the non-emission area NEA. Redundant descriptions will be omitted.

Referring to FIG. 9, the first storage capacitor 250 includes a first capacitor electrode 251 and a second capacitor electrode 252.

The first capacitor electrode 251 may be disposed between the substrate 110 and the buffer layer 111 on the substrate 110. In addition, the first capacitor electrode 251 may be disposed in the non-emission area NEA and may be disposed on the same layer as the light blocking layer LS placed between the substrate 110 and the first active layer 124 of the first transistor 120. For example, the first capacitor electrode 251 may be disposed on the substrate 110 to be directly in contact with the substrate 110 and may extend to the non-emission area NEA. In this case, the first capacitor electrode 251 may be formed of a transparent conductive material. For example, the first capacitor electrode 251 may be formed of a transparent conductive material such as indium tin oxide (ITO) or indium zinc oxide (IZO).

The second capacitor electrode 252 is disposed on the buffer layer 111 and is disposed to overlap the first capacitor electrode 251. Also, the second capacitor electrode 252 may be disposed on the same layer as the first active layer 124 of the first transistor 120. For example, the second capacitor electrode 252 may be disposed on the first capacitor electrode 251 in the emission area EA to overlap the first capacitor electrode 251. The second capacitor electrode 252 may be formed of a transparent conductive material and may be formed of the semiconductor layer 153 which is conductive. For example, the semiconductor layer 153 may be formed of an oxide semiconductor material such as indium gallium zinc oxide (IGZO), zinc tin oxide (ZTO), or zinc indium oxide (ZIO) and then, become conductive.

In the display device 200 according to another exemplary embodiment of the present disclosure, by securing a greater amount of storage capacity, when an equal data voltage is supplied, the amount of current can increase to increase luminance, and a relatively low data voltage for the same luminance can be applied. Therefore, power consumption can be reduced.

In addition, in the display device 200 according to another exemplary embodiment of the present disclosure, the second capacitor electrode 252 is formed of a single conductive semiconductor layer 153, so that a process of depositing an additional transparent oxide layer on the semiconductor layer can be omitted. Thus, a simplified process can be allowed and a process time can be shortened.

The exemplary embodiments of the present disclosure can also be described as follows:

A display device according to an exemplary embodiment of the present disclosure includes a substrate including an emission area and a non-emission area and having a plurality of sub-pixels defined thereon, a driving transistor disposed in the non-emission area, a light emitting element disposed in the emission area, a first storage capacitor disposed in the emission area and a second storage capacitor disposed in the non-emission area.

The first storage capacitor may include a first capacitor electrode disposed between the substrate and a buffer layer on the substrate.

The display device may further include a light blocking layer that may be disposed in the non-emission area and may be disposed between the substrate and an active layer of the driving transistor, wherein the first storage capacitor may be disposed on the same layer as the light blocking layer.

The first storage capacitor further may include a second capacitor electrode disposed on the buffer layer and configured to overlap the first capacitor electrode.

The second capacitor electrode may be disposed on the same layer as the active layer of the driving transistor.

The second capacitor electrode may be formed of a transparent oxide layer.

The second capacitor electrode may be formed of a conductive semiconductor layer.

The first capacitor electrode and the second capacitor electrode may be formed of a transparent conductive material.

An area of the first capacitor electrode may be greater than that of the second capacitor electrode.

The second storage capacitor may include a third capacitor electrode extending from the first capacitor electrode and disposed on the same layer as the first capacitor electrode; and a fourth capacitor electrode extending from the second capacitor electrode and disposed on the same layer as the second capacitor electrode.

The third capacitor electrode may be integrally formed with the light blocking layer.

The third capacitor electrode may have a stacked structure in which a transparent oxide layer and a metal layer are stacked.

The fourth capacitor electrode may be formed of a transparent oxide layer.

The fourth capacitor electrode may be formed of a conductive semiconductor layer.

The second storage capacitor further may include a fifth capacitor electrode disposed on the fourth capacitor electrode to overlap the fourth capacitor electrode and disposed on the same layer as a gate electrode of the driving transistor.

What is claimed is:

1. A display device, comprising:
a substrate including an emission area and a non-emission area, the emission area comprising a sub-pixel;
a light emitting element in the emission area, the light emitting element configured to emit light;
a driving transistor in the non-emission area, the driving transistor configured to drive the light emitting element;
a first storage capacitor in the emission area; and
a second storage capacitor in the non-emission area.

2. The display device of claim 1, further comprising:
a buffer layer on the substrate,
wherein the first storage capacitor includes a first capacitor electrode between the substrate and the buffer layer.

3. The display device of claim 2, wherein the driving transistor comprises an active layer, the display device further comprising:
a light blocking layer in the non-emission area, the light blocking layer between the substrate and the active layer of the driving transistor,
wherein the first storage capacitor is on a same layer as the light blocking layer.

4. The display device of claim 3, wherein the first storage capacitor further includes a second capacitor electrode on the buffer layer, the second capacitor electrode overlapping the first capacitor electrode.

5. The display device of claim 4, wherein the second capacitor electrode is on a same layer as the active layer of the driving transistor.

6. The display device of claim 5, wherein the second capacitor electrode comprises a transparent oxide layer.

7. The display device of claim 5, wherein the second capacitor electrode comprises a conductive semiconductor layer.

8. The display device of claim 4, wherein the first capacitor electrode and the second capacitor electrode comprise a transparent conductive material.

9. The display device of claim 4, wherein an area of the first capacitor electrode is greater than an area of the second capacitor electrode.

10. The display device of claim 4, wherein the second storage capacitor includes:
a third capacitor electrode extending from the first capacitor electrode and on a same layer as the first capacitor electrode; and
a fourth capacitor electrode extending from the second capacitor electrode and on a same layer as the second capacitor electrode.

11. The display device of claim 10, wherein the third capacitor electrode is integrally formed with the light blocking layer.

12. The display device of claim 10, wherein the third capacitor electrode comprises a transparent oxide layer and a metal layer that is stacked on the transparent oxide layer.

13. The display device of claim 10, wherein the fourth capacitor electrode comprises a transparent oxide layer.

14. The display device of claim 10, wherein the fourth capacitor electrode comprises a conductive semiconductor layer.

15. The display device of claim 10, wherein the second storage capacitor further includes a fifth capacitor electrode that overlaps the fourth capacitor electrode and is on a same layer as a gate electrode of the driving transistor.

16. A display device, comprising:
a substrate having an emission area and a non-emission area;
a light emitting element on the substrate in the emission area, the light emitting element configured to emit light;
a driving transistor on the substrate in the non-emission area, the driving transistor configured to drive the light emitting element;
a first electrode on the substrate, the first electrode having a first portion in the emission area and a second portion in the non-emission area;
a second electrode on the substrate, the second electrode having a first portion in the emission area and a second portion in the non-emission area,
wherein the first portion of the first electrode and the first portion of the second electrode overlap each other in the emission area such that a first storage capacitor is in the emission area, and the second portion of the first electrode and the second portion of the second electrode overlap each other in the non-emission area such that a second storage capacitor is in the non-emission area.

17. The display device of claim 16, wherein the first portion and the second portion of the second electrode are directly on the substrate.

18. The display device of claim 16, further comprising:
a buffer layer on the second electrode, the buffer layer extending across the emission area and the non-emission area;
a semiconductor layer on the buffer layer, the semiconductor layer extending across the emission area and non-emission area; and
a light blocking layer between the buffer layer and the second electrode in the non-emission area,
wherein the first portion and the second portion of the first electrode are on the semiconductor layer.

19. The display device of claim 16, further comprising:
a gate insulating layer on the first electrode; and
a third electrode on the gate insulating layer in the non-emission area, the third electrode overlapping the second portion of the first electrode.

20. A display device, comprising:
a substrate having an emission area and a non-emission area;
a light emitting element on the substrate in the emission area, the light emitting element configured to emit light;
a driving transistor on the substrate in the non-emission area, the driving transistor configured to drive the light emitting element;
a first storage capacitor in the emission area, the first storage capacitor connected between the driving transistor and the light emitting element; and
a second storage capacitor in the non-emission area, the second storage capacitor connected between the driving transistor and the light emitting element.

21. The display device of claim 20, wherein the first storage capacitor includes a first electrode and a second electrode, and the second storage capacitor comprising a third electrode and a fourth electrode,
wherein the first electrode and the third electrode are electrically connected, and the second electrode and the fourth electrode are electrically connected.

22. The display device of claim 21, wherein the first electrode and the third electrode are directly on the substrate.

23. The display device of claim 21, further comprising:
a buffer layer on the first electrode, the buffer layer extending across the emission area and non-emission area;
a semiconductor layer on the buffer layer, the semiconductor layer extending across the emission area and the non-emission area; and
a light blocking layer between the buffer layer and the first electrode in the non-emission area,
wherein the second electrode and the fourth electrode are on the semiconductor layer.

24. The display device of claim 21, further comprising:
a gate insulating layer on the second electrode;
wherein the second storage capacitor further comprises a fifth electrode on the gate insulating layer in the non-emission area, the fifth electrode overlapping the fourth electrode.
